(19) United States
(12) Patent Application Publication
(10) Pub. No.: US 2025/0038032 A1
(43) Pub. Date: Jan. 30, 2025

(54) TRANSFER UNIT AND TRANSFER ROBOT SYSTEM INCLUDING TRANSFER ROBOT

(71) Applicant: SEMES CO., LTD., Cheonan-si (KR)

(72) Inventor: Donghoon Yang, Cheonan-si (KR)

(21) Appl. No.: 18/764,435

(22) Filed: Jul. 5, 2024

(30) Foreign Application Priority Data
Jul. 26, 2023 (KR) 10-2023-0097699

(51) Int. Cl. H01L 21/68; H01L 21/677; H01L 21/687

(52) U.S. Cl. CPC H01L 21/681; H01L 21/67712; H01L 21/68707

(57) ABSTRACT

A transfer robot, which is configured to recognize a position of another robot loaded with a carrier and dock with the other robot, the transfer robot providing a first surface and a second surface opposite to the first surface, the transfer robot including a lower stage providing a first space for loading the carrier loaded on the other robot, a first camera disposed on the first surface and configured to recognize the position of the other robot and generate position information of the other robot, a robot arm configured to hold the carrier, a driving unit capable of aligning the transfer robot with the other robot by moving the transfer robot, and a controller electrically connected to the first camera, the robot arm, and the driving unit to receive the position information generated by the first camera.

### CROSS-REFERENCE TO RELATED APPLICATION

This application is based on and claims priority under 35 U.S.C. § 119 to Korean Patent Application No. 10-2023-0097699, filed on Jul. 26, 2023, in the Korean Intellectual Property Office, the disclosure of which is incorporated by reference herein in its entirety.

### BACKGROUND

### 1. Field

One or more embodiments relate to a transfer unit and a transfer robot system, and more particularly, to a transfer unit including a transfer robot that transfers a carrier in which an object is accommodated and a transfer robot system.

### 2. Description of the Related Art

Generally, in order to manufacture semiconductor devices, various kinds of processes such as deposition, photography, and etching processes are performed, and devices that perform each of these processes are placed within a semiconductor manufacturing line. Objects, such as wafers for performing a process for manufacturing a semiconductor device, may be provided to each semiconductor processing device while stored in a container such as a Front Opening Unified Pod (FOUP). Additionally, the objects on which the process has been performed may be recovered in containers from each semiconductor processing device, and the recovered containers may be returned to the outside.

In order to increase processing efficiency for semiconductor device manufacturing, the time for transfer robots to transfer containers between semiconductor processing devices, such as an Autonomous Motor Robot (AMR), must be shortened. A plurality of transfer robots may be provided, and if even one of the transfer robots fails to transfer the container due to a failure, error, or discharge, there is a problem that the processing efficiency of semiconductor device manufacturing is reduced.

### SUMMARY

One or more embodiments include a transfer unit and a transfer robot system that may maintain processing efficiency in manufacturing a semiconductor device by docking a normally operating transfer robot with a troubled transfer robot.

The problems to be solved by the technical spirit of the inventive concept are not limited to the problems mentioned above, and other problems not mentioned will be clearly understood by those skilled in the art from the following description.

Additional aspects will be set forth in part in the description which follows and, in part, will be apparent from the description, or may be learned by practice of the presented embodiments of the disclosure.

According to one or more embodiments, a transfer robot which is configured to recognize a position of another robot loaded with a carrier and dock with the other robot, the transfer robot providing a first surface and a second surface opposite to the first surface, the transfer robot includes a lower stage providing a first space for loading the carrier loaded on the other robot, a first camera disposed on the first surface and configured to recognize the position of the other robot and generate position information of the other robot, a robot arm configured to hold the carrier, a driving unit capable of aligning the transfer robot with the other robot by moving the transfer robot, and a controller electrically connected to the first camera, the robot arm, and the driving unit to receive the position information generated by the first camera, wherein the control unit is configured to send a driving signal to the driving unit so that the transfer robot docks with the other robot based on the position information.

According to an embodiment, the transfer robot may further include a first landmark attached to the first surface and a second landmark attached to the second surface, wherein the first landmark may include position information that the surface to which the first landmark is attached is the first surface, and the second landmark may include position information that the surface to which the second landmark is attached is the second surface.

According to an embodiment, the first landmark and the second landmark are QR code images.

According to an embodiment, the control unit may send an electrical signal to the robot arm to pick the carrier loaded on the other robot when the transfer robot docks with the other robot.

According to an embodiment, the transfer robot may further include an upper stage providing a second space for loading the carrier, wherein a vertical level from the lowest surface of the transfer robot of the upper stage is higher than a vertical level from the lowest surface of the transfer robot of the lower stage.

According to one or more embodiments, a transfer unit includes a first transfer robot providing a space for transferring and loading a carrier including an object on shelves arranged in left-right and up-down directions, a first surface, and a second surface opposite to the first surface, a second transfer robot providing a space for transferring and loading the carrier, a third surface, and a fourth surface opposite to the third surface, and a crane provided in the left and right directions and a lifting belt provided along the crane and coupled to the first transfer robot and the second transfer robot, wherein the first transfer robot includes a first landmark attached to the first surface, a second landmark attached to the second surface, and a first driving unit that moves the first transfer robot in the left and right directions or up and down directions, wherein the second transfer robot includes a third landmark disposed on the third surface, a fourth landmark disposed on the fourth surface, and a second driving unit that moves the second transfer robot in the left and right direction or up and down direction.

According to an embodiment, the first landmark may include information that the surface to which the first landmark is attached is the first surface of the first transfer robot, the second landmark may include information that the surface to which the second landmark is attached is the second surface of the first transfer robot, the third landmark may include information that the surface to which the third landmark is attached is the third surface of the second transfer robot, and the fourth landmark may include information that the surface to which the fourth landmark is attached is the fourth surface of the second transfer robot.

According to an embodiment, the first transfer robot may include a first lower stage providing a first space for loading the carrier, and a first upper stage providing a second space for loading the carrier, wherein a vertical level from the lowest surface of the first transfer robot of the first upper stage may be higher than a vertical level from the lowest surface of the first transfer robot of the first lower stage.

According to an embodiment, in the left and right direction, the first lower stage may be positioned closer to the first landmark than the first upper stage.

According to an embodiment, the second transfer robot may include a second lower stage providing a third space for loading the carrier, and a second upper stage providing a fourth space for loading the carrier, wherein the vertical level from the lowest surface of the second transfer robot of the second upper stage may be higher than the vertical level from the lowest surface of the second transfer robot of the second lower stage.

According to an embodiment, in the left and right direction, the second upper stage may be positioned closer to the fourth landmark than the second lower stage.

According to an embodiment, the first transfer robot may include a first camera disposed on the first surface, a second camera disposed on the second surface, and a first controller electrically connected to the first driving unit, the first camera, and the second camera.

According to an embodiment, the first camera may be configured to receive position information about the second transfer robot by photographing the fourth landmark of the second transfer robot and transmit a driving signal of the first transfer robot to the first controller based on the position information.

According to an embodiment, the second transfer robot may include a third camera disposed on the third surface, a fourth camera disposed on the fourth surface, and a second controller electrically connected to the second driving unit, the third camera, and the fourth camera.

According to an embodiment, the third camera may be configured to receive position information about the first transfer robot by photographing the third landmark of the first transfer robot and transmit a driving signal of the second transfer robot to the second controller based on the position information.

According to an embodiment, the first landmark, the second landmark, the third landmark, and the fourth landmark may be quick response (QR) code images.

According to one or more embodiments, in a transfer robot system comprising a first transfer robot, a second transfer robot for loading carriers including semiconductor wafers on shelves arranged in a left-right direction and up-down direction, a crane provided in the left-right direction, and a lifting belt provided along the crane and coupled to the first transfer robot and the second transfer robot, the first transfer robot providing a first surface includes a first lower stage providing a first space for loading the carrier, a first upper stage positioned at a higher vertical level than the first lower stage and providing a second space for loading the carrier, a first landmark attached to the first surface, the first landmark including position information that the surface to which the first landmark is attached is the first surface, a first camera disposed on the first surface, and a first robot arm configured to hold the carrier, and the second transfer robot providing a second surface includes a second lower stage providing a second space for loading the carrier, a second upper stage positioned at a higher vertical level than the second lower stage and providing a second space for loading the carrier, a second camera configured to recognize the first landmark of the first transfer robot and generate position information of the first landmark, a second robot arm configured to hold the carrier, and a driving unit capable of moving the second transfer robot in one direction using the lifting belt, wherein the second transfer robot drives the second robot arm to transfer the carrier loaded on the first upper stage when the first surface of the first transfer robot and the second surface of the second transfer robot face each other.

According to an embodiment, in left and right direction, the first lower stage is positioned closer to the first landmark than the first upper stage.

According to an embodiment, the second transfer robot may include a second landmark attached to the second surface, the second landmark including position information that the surface to which the second landmark is attached is the second surface, wherein the first transfer robot drives the first robot arm to transfer the carrier loaded on the second upper stage when the first surface of the first transfer robot and the second surface of the second transfer robot face each other.

According to an embodiment, the first landmark and the second landmark may be quick response (QR) code images.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a top view of a transfer system according to an embodiment;

FIG. 2 is a schematic front cross-sectional view to explain a stocker according to an embodiment;

FIG. 3 is a schematic plane cross-sectional view of a stocker according to an embodiment;

FIG. 4 is a structural diagram briefly showing a system of a plurality of transfer robots according to an embodiment;

FIG. 5 is a perspective view showing a plurality of transfer robots according to an embodiment;

FIG. 6 is a plan view of a first transfer robot shown in FIG. 5 viewed from the front;

FIG. 7 is a perspective view showing a plurality of transfer robots according to another embodiment;

FIG. 8 is a plan view of a first transfer robot shown in FIG. 7 viewed from the front;

FIG. 9 is a flowchart sequentially showing a control method of a transfer unit according to an embodiment; and

FIG. 10 is a flowchart sequentially showing a control method of a transfer unit according to another embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Reference will now be made in detail to embodiments, examples of which are illustrated in the accompanying drawings so that those of ordinary skill in the art may readily understand. However, the embodiments may be embodied in many different forms and should not construed as being limited to the following description. Additionally, in describing the inventive concept, when practical descriptions with respect to related known function and configuration may unnecessarily make the scope of the inventive concept unclear, the descriptions thereof will be omitted. In addition, the same symbols are used throughout the drawings for parts that perform similar functions and actions.

It should be understood that, when a part “comprises” or “includes” an element in the specification, unless otherwise defined, it is not excluding other elements but may further include other elements. Specifically, the terms “comprise” and/or “comprising” when used in this specification, specify the presence of stated features, integers, steps, operations, elements, and/or components, but do not preclude the presence or addition of one or more other features, integers, steps, operations, elements, components, and/or groups thereof.

The singular forms include the plural forms unless the context clearly indicates otherwise. Additionally, the shapes and sizes of elements in the drawings may be exaggerated for clearer explanation.

The transfer system according to embodiments may be used to transport containers. In particular, the transfer system according to embodiments may transfer a container containing an article. The article may be a substrate such as a wafer or a reticle. The container in which the article is stored may be a Front Opening Unified Pod (FOUP). Additionally, the container in which the article is stored may be a pod (POD). Additionally, the container in which the article is stored may be the carrier C. Additionally, the container in which the articles are stored may include a magazine for storing a plurality of printed circuit boards, a tray for storing a plurality of semiconductor packages, etc.

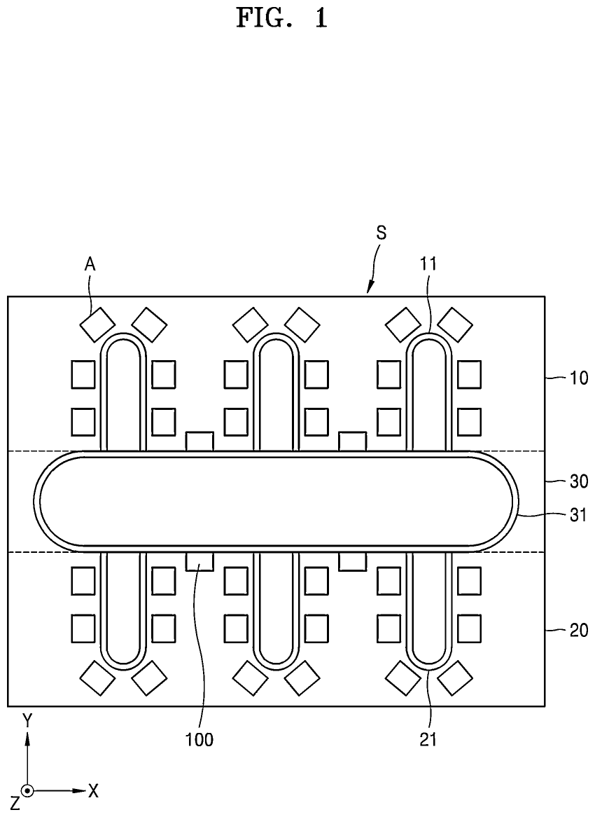

Hereinafter, an example is given in which a transfer system transfers a cassette containing a substrate, such as a wafer, to semiconductor processing devices placed on a semiconductor manufacturing line. Hereinafter, embodiments of the disclosure will be described in detail with reference to FIGS. 1 to 10. In addition, hereinafter, a direction perpendicular to a first direction (X direction) when viewed from the top is defined as a second direction (Y direction), and a direction perpendicular to the first direction (X direction) and the second direction (Y direction) is defined as a third direction (Z direction).

FIG. 1 is a top view of a transfer system S according to an embodiment. Referring to FIG. 1, the transfer system S according to an embodiment may include a first facility region 10, a second facility region 20, a transfer region 30, and a stocker 100.

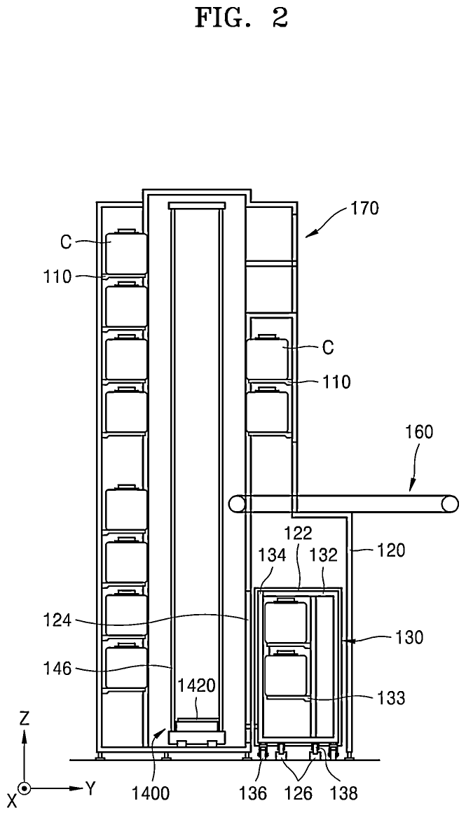

The first facility region 10 and the second facility region 20 are regions where a semiconductor manufacturing device A is installed. The transfer region 30 is a region where a rail 31, which holds the carriers C (see FIG. 2) and allows delivery vehicles to travel at high speed, is installed.

The first facility region 10 may have a plurality of semiconductor manufacturing devices A installed and extend lengthwise in a first direction (X direction). The second facility region 20 may have a plurality of semiconductor manufacturing devices A installed and extend lengthwise in the first direction (X direction). For example, the plurality of semiconductor manufacturing devices A may be devices capable of performing processes such as photography, etching, ashing, ion implantation, thin film deposition, and cleaning. The first facility region 10 and the second facility region 20 may be provided to be symmetrical to each other with respect to the transfer region 30. However, the present disclosure is not limited thereto, and the first facility region 10 and the second facility region 20 may be modified in various ways.

The stocker 100 may store a carrier C (see FIG. 2) in which the substrate may be stored. The stocker 100 may transfer the carrier C containing the substrate (see FIG. 2) to a vehicle. The stocker 100 may be provided in the first facility region 10 and/or the second facility region 20.

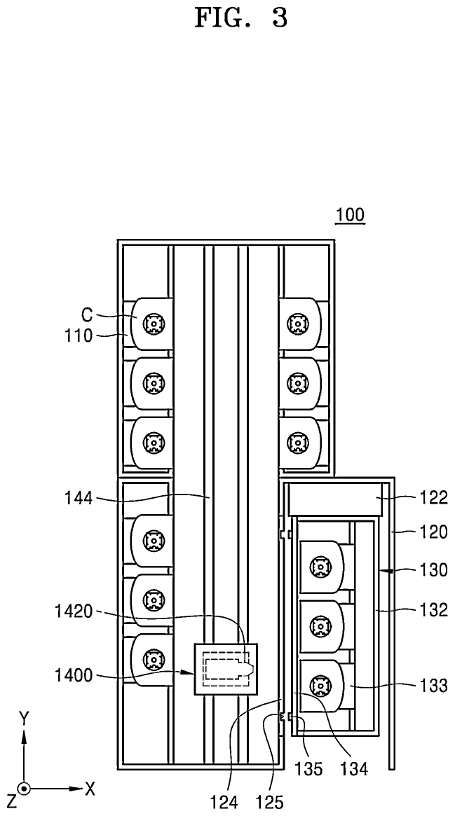

FIG. 2 is a schematic front cross-sectional view to explain a stocker 100 according to an embodiment, and FIG. 3 is a schematic plan cross-sectional view illustrating the stocker 100 according to an embodiment.

Referring to FIGS. 2 and 3, the stocker 100 may include a first shelf 110, a cart-receiving unit 120, a transfer robot 1400, and a port 160.

The first shelf 110 may be provided in a structure that may accommodate the carrier C. The first shelf 110 may be provided in plural numbers. The first shelves 110 may be arranged in the first direction (X direction) and a third direction (Z direction). For example, as shown, the first shelves 110 may be arranged in two rows facing each other with respect to a first lifting belt 144 of the transfer robot 1400. As another example, although not shown, the first shelves 110 may be arranged in one row.

The cart-receiving unit 120 may provide a space to accommodate a cart 130. The cart-receiving unit 120 may be arranged parallel to the first shelves 110. The cart-receiving unit 120 may have an internal space to accommodate the cart 130 and may have a substantially hollow hexahedral shape. One side of the cart-receiving unit 120 may be open to allow the cart 130 to enter and exit. Additionally, the cart-receiving unit 120 may include a docking plate 122, a shutter 124, a docking rail 126, a cart detection sensor (not shown), and a docking detection sensor (not shown).

The docking plate 122 may dock and secure the cart 130 when the cart 130 is accommodated in the cart-receiving unit 120. The docking plate 122 may be arranged to extend upward and downward at an end in a direction in which the cart 130 moves to be accommodated in the cart-receiving unit 120. The docking plate 122 may have a groove into which the cart 130 is inserted for docking with the cart 130 or may be provided with a cylinder for fixing the cart 130.

The docking rail 126 may extend in a moving direction of the cart 130 on a bottom surface of the cart-receiving unit 120. The docking rail 126 may provide a path for guiding the cart 130 so that the cart 130 is docked to the docking plate 122. Accordingly, the cart 130 may be accurately and stably docked with the docking plate 122.

A balance detection sensor (not shown) may be provided adjacent to the docking plate 122. For example, the cart detection sensor (not shown) may be provided on a bottom or side adjacent to the docking plate 122. The cart detection sensor (not shown) detects the presence of the cart 130 inside the cart-receiving unit 120. The vehicle detection sensor (not shown) may be a proximity sensor. The docking detection sensor (not shown) may be provided on the docking plate 122 and detect whether the cart 130 is fixed to the docking plate 122. For example, the docking detection sensor (not shown) may be provided in the groove of the docking plate 122 to detect whether the cart 130 is inserted into the groove, or whether the cart 130 is coupled to the cylinder of the docking plate 122. Therefore, docking defects in the cart 130 may be quickly confirmed using the cart detection sensor (not shown) and the docking detection sensor (not shown). Therefore, the cart 130 may be accurately and stably docked to the docking plate 122.

The cart 130 is accommodated in the cart-receiving unit 120 through one open side of the cart-receiving unit 120, and is docked and fixed with the docking plate 122 of the cart-receiving unit 120. The cart 130 accommodates a plurality of carriers C. Semiconductor wafers may be accommodated inside the plurality of carriers C.

Specifically, the cart 130 may include a body 132, a door 134, moving wheels 136, and docking wheels 138. The body 132 has a hollow hexahedral shape with one side open. The body 132 is provided with a plurality of second shelves 133. The carriers C may be stored in the second shelves 133.

The door 134 may be provided on one side of the body 132 and to be able to move up and down. At this time, a guide provided on the body 132 may guide the vertical movement of the door 134. Accordingly, the door 134 may open and close the opened portion of the body 132. An O-ring (not shown) may be provided between the body 132 and the door 134 for sealing. For example, the O-ring may be provided along the circumference of one side of the body 132. Accordingly, if the opened portion of the body 132 is blocked by the door 134, the interior of the body 132 may be in a sealed state. Therefore, the carriers C may be prevented from being contaminated by external particles when the carriers C are loaded and transported on the cart 130.

The moving wheels 136 may be provided on a lower surface of the body 132 to move the body 132. An example of the moving wheels 136 may be a rotatable caster. Because the moving wheels 136 are provided, an operator may easily move the cart 130. The docking wheels 138 are provided on the lower surface of the body 132. At this time, the docking wheels 138 are fixed without rotating. The docking wheels 138 are used only when the cart 130 is docked with the docking plate 122 and are not used when the cart 130 is moved.

The docking wheels 138 may move along the docking rails 126. Because the cart 130 is guided by the docking rail 126, the cart 130 may be stably docked to the docking plate 122.

The docking wheels 138 may be positioned in another line, not the same line as the line where the moving wheels 136 are positioned. Therefore, when the docking wheels 138 move along the docking rail 126, the docking wheels 138 may not be interfered with by the moving wheels 136.

Additionally, a height of the docking wheels 138 may be higher than a height of the moving wheels 136. Accordingly, the docking wheels 138 may easily enter the docking rail 126 provided on an inner bottom surface of the cart-receiving unit 120.

The height of the docking wheels 138 may be the same as the height of the moving wheels 136.

The cart-receiving unit 120 may further include the shutter 124. If the cart 130 is accommodated in the cart-receiving unit 120 and docked with the docking plate 122, the shutter 124 may be disposed to face the door 134 of the cart 130.

The shutter 124 may have a receiving groove 125 for accommodating a link block 135 protruding from the door 134 of the cart 130. At this time, the link block 135 and the receiving groove 125 are disposed at corresponding heights and positions. The shutter 124 moves toward the cart 130 to accommodate the link block 134 in the receiving groove 125, and thus, the shutter 124 and the door 134 are coupled. When the shutter 124 and the door 134 are coupled, the door 134 of the cart 130 may be opened and closed while the shutter 124 moves vertically, that is, up and down.

The transfer robot 1400 may transport the carrier C within the stocker 100. The transfer robot 1400 may load the carrier C onto the shelves 110 and 133 or unload the carrier C from the first and second shelves 110 and 133. Also, the transfer robot 1400 may transfer the carrier C between the shelves 110 and 130 and between a first port 150 and a second port 160, which is described below. The transfer robot 1400 may include a robot arm 1420, a first lifting belt 144, and a second lifting belt 146.

The transfer robot 1400 may be provided between the first shelves 110 arranged in two rows. That is, based on the first lifting belt 144 of the transfer robot 1400, some of the first shelves 110 are disposed on one side of the first lifting belt 144, and some other first shelves 110 may be disposed on the other side of the first lifting belt 144.

The robot arm 1420 of the transfer robot 1400 may be configured to move toward the first shelves 110 and the second shelves 133. For example, the robot arm 1420 included in the transfer robot 1400 may be provided so that a length thereof may extend and/or contract. Additionally, the robot arm 1420 may have a hand capable of loading or unloading the carrier C into the first shelf 110, the first port 150 and the second port 160, which is described below. The hand of the robot arm 1420 may hold and transport the carrier C.

The first lifting belt 144 may guide the robot arm 1420 in a first direction (X direction). The second lifting belt 146 may guide the robot arm 1420 in the third direction (Z direction). Additionally, the transfer robot 1400 may include a driver (not shown) so that the robot arm 1420 may move along the first lifting belt 144 and the second lifting belt 146. As an example, the transfer robot 1400 may be configured to include a drive motor and a power transmission device including a timing belt and pulleys.

Additionally, the stocker 100 according to an embodiment may include a port 160. The port 160 may be provided in a shelf shape. One side of the port 160 may be open toward a guide rail 144 of the transfer robot 1400. Both sides of the port 160 are open, so that the carriers C stored and returned in the stocker 100 may be taken out of the stocker 100 through the port 160.

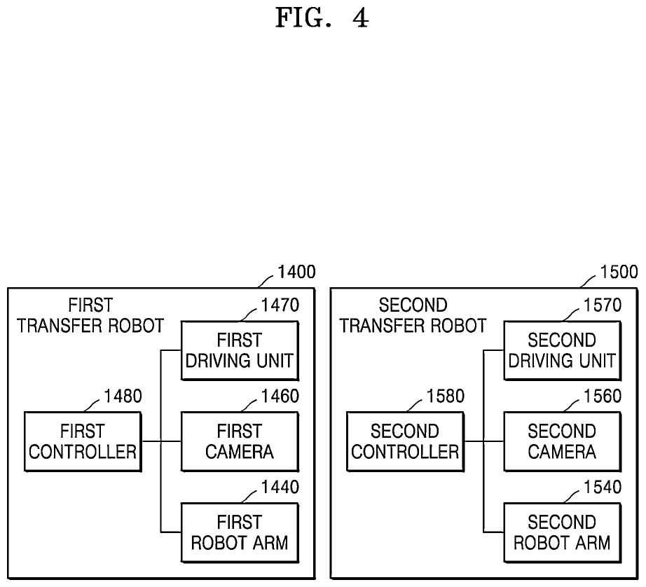

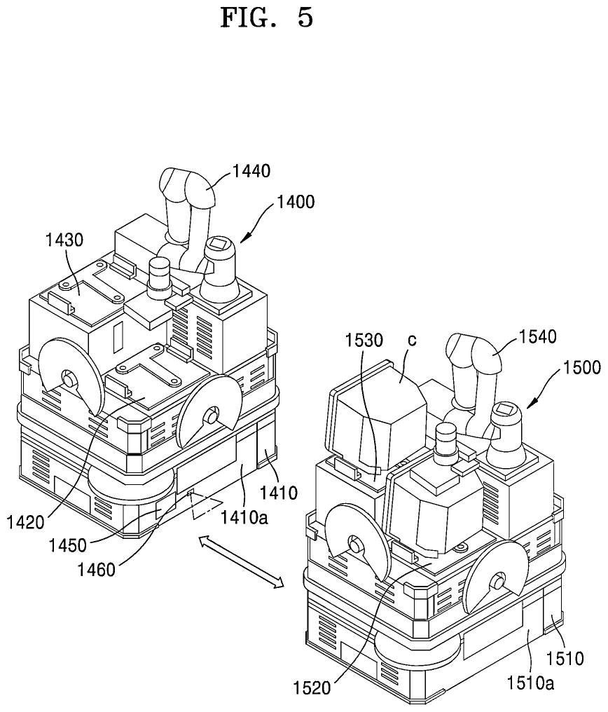

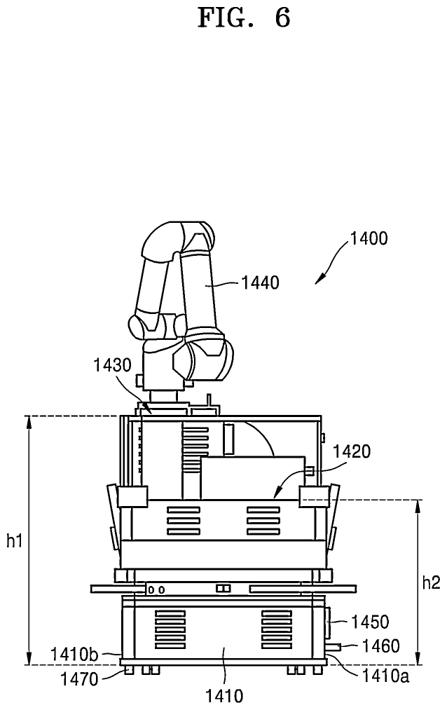

FIG. 4 is a structural diagram briefly showing a system of a plurality of transfer robots according to an embodiment. FIG. 5 is a perspective view showing a plurality of transfer robots according to an embodiment, and FIG. 6 is a plan view of a first transfer robot 1400 shown in FIG. 5 viewed from the front.

Referring to FIGS. 4 to 6, the first transfer robot 1400 according to an embodiment may include a first body 1410, a first lower stage 1420, a first upper stage 1430, a first robot arm 1440, a landmark 1450, a first camera 1460, a first driving unit 1470, and a first controller 1480. The first controller 1480 may be electrically connected to the first camera 1460, the first driving unit 1470, and the first robot arm 1440 and may send driving signals thereto. The first controller 1480 may include memory devices, such as Read Only Memory (ROM) and Random Access Memory (RAM), and a processor configured to perform predetermined operations and algorithms, for example, a microprocessor, a central processing unit (CPU), a Graphics Processing Unit (GPU), etc.

Hereinafter, configurations of the first transfer robot 1400 and the second transfer robot 1500 are described in detail. The first body 1410 of the first transfer robot 1400 may function as a supporter at a lower end of the first transfer robot 1400 and provide a first surface 1410a and a second surface 1410b opposite to the first surface 1410a.

Also, the first transfer robot 1400 may include the first lower stage 1420 and the first upper stage 1430 that provide a space to accommodate the carrier C on the first body 1410. As shown in FIG. 6, the first lower stage 1420 may be disposed closer to the first surface 1410a of the first body 1410 than to the first upper stage 1430. That is, based on FIG. 6 in which the first transfer robot 1400 is viewed from the front, from the left to right direction, the first lower stage 1420 may be disposed closer to the first surface 1410a of the first body 1410 and the landmark 1450 than to the first upper stage 1430. On the other hand, the first upper stage 1430 may be disposed closer to the second surface 1410b of the first body 1410 than to the first lower stage 1420.

A vertical level h1 of the first upper stage 1430 with respect to the lowermost surface of the first body 1410 may be higher than a vertical level h2 of the first lower stage 1420 with respect to the lowermost surface of the first body 1410. The first lower stage 1420 may provide a first space for loading the carrier C, and the first upper stage 1430 may provide a second space for loading the carrier C.

The first transfer robot 1400 may include a first robot arm 1440 disposed on one surface at the same vertical level h1 as the first upper stage 1430. The first robot arm 1440 may be configured to hold a carrier C that may be positioned on the first lower stage 1420 or the first upper stage 1430.

According to one embodiment, the landmark 1450 may be attached to the first surface 1410a of the first body 1410 of the first transfer robot 1400. For example, the landmark 1450 may be a quick response (QR) code including information that the surface to which the landmark 1450 is attached is the first surface 1410a of the first transfer robot 1400.

According to one embodiment, the first driving unit 1470 of the first transfer robot 1400 may move the first transfer robot 1400 in one direction using the first lifting belt 144 (see FIG. 3) or the second lifting belt 146 (see FIG. 2). At this time, the one direction may be the left and right direction as indicated by the arrow shown in FIG. 5 or may be forward and backward.

The second transfer robot 1500 according to an embodiment may include a second body 1510, a second lower stage 1520, a second upper stage 1530, a second robot arm 1540, a second camera 1560, a second driving unit 1570, and a second controller 1580. Among the components of the second transfer robot 1500 and the components of the first transfer robot 1400, corresponding components may be substantially the same as each other. The second controller 1580 may electrically connected to the second camera 1560, the second driving unit 1570, and the second robot arm 1540 and may send driving signals to the components. The second controller 1580 may include memory devices, such as ROM and RAM, and a processor configured to perform predetermined operations and algorithms, for example, a microprocessor, a CPU, a GPU, etc.

The second body 1510 of the second transfer robot 1500 may function as a supporter at a lower end of the second transfer robot 1500 and provide a third surface 1510a and a fourth surface 1510b opposite to the third surface 1510a.

In addition, the second transfer robot 1500 may include a second lower stage 1520 and a second upper stage 1530 that provide a space to accommodate the carrier C on the second body 1510. The second lower stage 1520 may be disposed closer to the third surface 1510a of the second body 1510 than to the second upper stage 1530. That is, based on the front of the second transfer robot 1500, in the left and right direction, the second lower stage 1520 may be disposed closer to the third surface 1510a of the second body 1510 than to the second upper stage 1530.

A vertical level h1 of the second upper stage 1530 with respect to the lowermost surface of the second body 1510 may be higher than a vertical level h2 of the second lower stage 1520 with respect to the lowermost surface of the second body 1510. The second lower stage 1520 may provide a third space for loading the carrier C, and the second upper stage 1530 may provide a fourth space for loading the carrier C.

The second transfer robot 1500 may include a second robot arm 1540 disposed on one surface at the same vertical level h1 as the second upper stage 1530. The second robot arm 1540 may be configured to hold a carrier C that may be positioned on the second lower stage 1520 or the second upper stage 1530.

According to one embodiment, the second driving unit 1570 of the second transfer robot 1500 may move the second transfer robot 1500 in one direction using a lifting belt. At this time, the one direction may be the left and right direction as indicated by the arrow shown in FIG. 5 or may be forward and backward.

According to one embodiment, the second camera 1460b of the second transfer robot 1500 may be configured to photograph a first landmark of the first transfer robot 1400 and receive position information about the first transfer robot 1400. The second controller 1580 of the second transfer robot 1500 may be configured to generate a driving signal of the second transfer robot 1500 based on position information about the first transfer robot 1400 received from the second camera 1460b and to transmit position information to the second driving unit 1570. That is, the second transfer robot 1500 may approach and align with the first transfer robot 1400 based on information about the position of the first transfer robot 1400. The second transfer robot 1500 that approaches the first transfer robot 1400 may transfer or load the carrier C through the second robot arm 1540. The second robot arm 1540 may be disposed closer to the fourth surface 1510b than to the third surface 1510a of the second transfer robot 1500. Also, the second robot arm 1540 may be disposed closer to the second upper stage 1530 than to the second lower stage 1520. Accordingly, the second robot arm 1540 of the second transfer robot 1500, which approaches the first transfer robot 1400, may pick up the carrier C from the second upper stage 1530 and load the carrier C on the first lower stage 1420 of the first transfer robot 1400. That is, the second camera 1560 photographs the landmark 1450 of the first transfer robot 1400, and if the second controller 1580, which is electrically connected to the second camera 1560, determines that the fourth surface 1510b of the second transfer robot 1500 faces the first surface 1410a of the first transfer robot 1400, the second robot arm 1540 picks up and/or loads the carrier C.

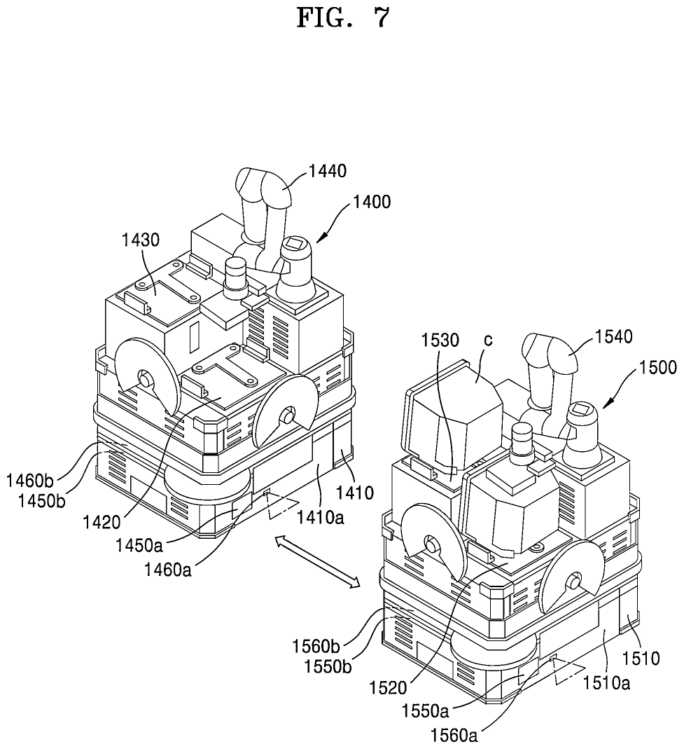

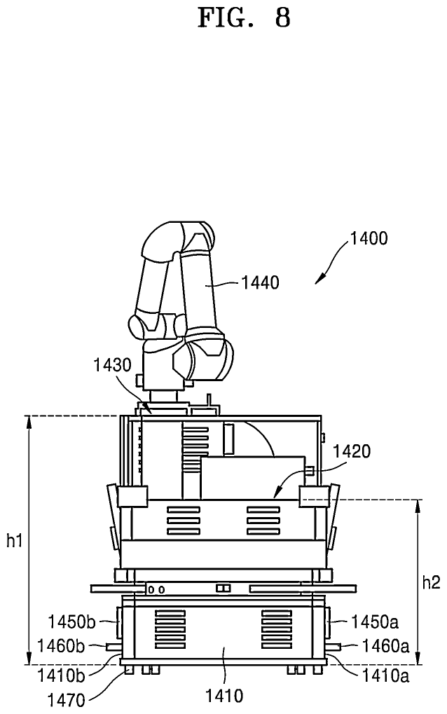

FIG. 7 is a perspective view showing a plurality of transfer robots according to another embodiment, and FIG. 8 is a plan view of the first transfer robot 1400 shown in FIG. 7 viewed from the front.

When the first transfer robot 1400 and the second transfer robot 1500 shown in FIGS. 7 and 8 are compared to the first transfer robot 1400 and the second transfer robot 1500 shown in FIGS. 5 and 6, they are almost identical or similar except that each of the first and second transfer robots 1400 and 1500 includes two cameras and two landmarks. Therefore, the descriptions of the components already given with reference to FIGS. 5 and 6 are simplified or omitted.

According to one embodiment, the first body 1410 of the first transfer robot 1400 may provide the first surface 1410a and the second surface 1410b opposite to the first surface 1410a. At this time, the first transfer robot 1400 may include a first landmark 1450a attached to the first surface 1410a and a second landmark 1450b attached to the second surface 1410b. The second body 1510 of the second transfer robot 1500 may provide a third surface 1510a and a fourth surface 1510b opposite to the third surface 1510a. At this time, the second transfer robot 1500 may include a third landmark 1550a attached to the third surface 1510a and a fourth landmark 1550b attached to the fourth surface 1510b.

At this time, the first landmark 1450a may include information that a surface to which the first landmark 1450a is attached is the first surface 1410a of the first transfer robot 1400, and the second landmark 1450b may include information that a surface to which the second landmark 1450b is attached is the second surface 1410b of the first transfer robot 1400. The third landmark 1550a may include information that a surface to which the third landmark 1550a is attached is the third surface 1510a of the second transfer robot 1500, and the fourth landmark 1550b may include information that a surface to which the third landmark 1550a is attached is the third surface 1510a of the second transfer robot 1500.

According to one embodiment, the first transfer robot 1400 may include a first camera 1460a disposed on the first surface 1410a, and a second camera 1460b disposed on the second surface 1410b. Additionally, the second transfer robot 1500 may include a third camera 1560a disposed on the third surface 1510a and a fourth camera 1560b disposed on the fourth surface 1510b. The first transfer robot 1400 may include a first controller 1480, which may be electrically connected to the first driving unit 1470, the first camera 1460, and the second camera 1460b of the first transfer robot 1400. Additionally, the second transfer robot 1500 may include a second controller 1580, which may be electrically connected to the second driving unit 1570, the third camera 1560a, and the fourth camera 1560b of the second transfer robot 1500.

FIG. 7 is a diagram illustrating a case when the first surface 1410a of the first transfer robot 1400 and the fourth surface 1510b of the second transfer robot 1500 face each other. The fourth camera 1560b of the second transfer robot 1500 may be configured to receive position information about the first transfer robot 1400 by photographing the first landmark 1450a of the first transfer robot 1400. The second controller 1580 of the second transfer robot 1500 may be configured to generate a driving signal of the second transfer robot 1500 based on the position information about the first transfer robot 1400 received from the fourth camera 1560b and transmit the driving signal to the second driver 1570. That is, the second transfer robot 1500 may approach and align with the first transfer robot 1400 based on position information about the first transfer robot 1400. The second transfer robot 1500, which has approached the first transfer robot 1400, may transfer or load the carrier C using the second robot arm 1540. The second robot arm 1540 may be disposed closer to the fourth surface 1510b of the second transfer robot 1500 than to the third surface 1510a. Additionally, the second robot arm 1540 may be placed closer to the second upper stage 1530 than to the second lower stage 1520. Accordingly, the second robot arm 1540 of the second transfer robot 1500, which has approached the first transfer robot 1400, may pick up the carrier C from the second upper stage 1530 and load the carrier C to the first lower stage 1420 of the first transfer robot 1400. That is, the second camera 1460b photographs the first landmark 1450a of the first transfer robot 1400, and if the second controller 1580, which is electrically connected to the second camera 1460b, determines that the fourth surface 1510b of the second transfer robot 1500 faces the first surface 1410a of the first transfer robot 1400, the second robot arm 1540 picks up and/or loads the carrier C.

On the other hand, although not shown in the drawing, the second surface 1410b of the first transfer robot 1400 and the third surface 1510a of the second transfer robot 1500 may face each other. In this case, the third camera 1560a of the second transfer robot 1500 may be configured to photograph the second landmark 1450b of the first transfer robot 1400 and receive position information about the first transfer robot 1400. The second controller 1580 of the second transfer robot 1500 may be configured to generate a driving signal of the second transfer robot 1500 based on the position information about the first transfer robot 1400 received from the third camera 1560a and transmit the driving signal to the second driver 1570. That is, the second transfer robot 1500 may approach and align with the first transfer robot 1400 based on position information about the first transfer robot 1400. The second transfer robot 1500, which has approached the first transfer robot 1400, may transfer or load the carrier C using the second robot arm 1540. The second robot arm 1540 of the second transfer robot 1500, which has approached the first transfer robot 1400, may pick up the carrier C from the second upper stage 1530 and transfer and load the carrier C on the first lower stage 1420 of the first transfer robot 1400. That is, the second camera 1460b photographs the second landmark 1450b of the first transfer robot 1400, and if the second controller 1580, which is electrically connected to the second camera 1460b, determines that the third surface 1510a of the first transfer robot 1400 faces the second surface 1410b of the first transfer robot 1400, the second robot arm 1540 picks up and/or loads the carrier C.

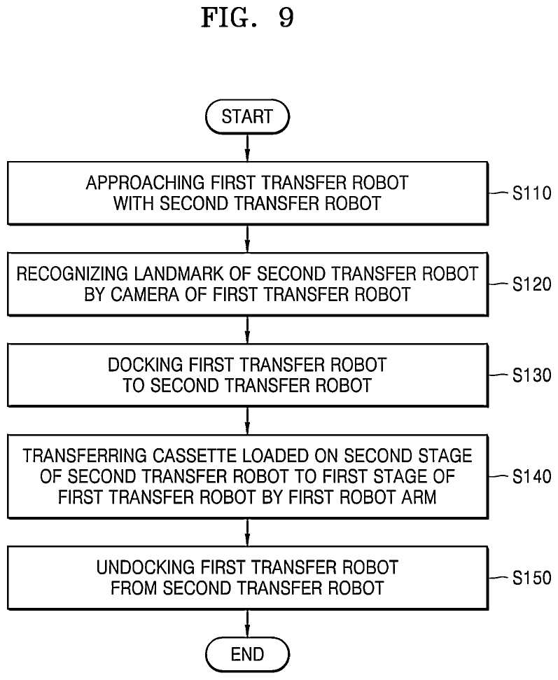

FIG. 9 is a flowchart sequentially showing a control method of a transfer unit according to an embodiment.

Referring to FIG. 9 together with FIGS. 4, 7, and 8 for convenience of explanation, the control method of the transfer unit according to an embodiment may first include an operation in which the first transfer robot 1400 approaches the second transfer robot 1500 (S110). Next, the control method of the transfer unit may include recognizing the fourth landmark 1550b disposed on the fourth surface 1510b of the second transfer robot 1500 by the first camera 1460 disposed on the first surface 1410a of the first transfer robot 1400 (S120). At this time, the fourth landmark 1550b may include information that the surface to which the fourth landmark 1550b is attached is the fourth surface 1510b of the second transfer robot 1500. The first camera 1460 may transmit information about the position of the second transfer robot 1500 to the first controller 1480. Thereafter, the control method of the transfer unit may include docking the first transfer robot 1400 to the second transfer robot 1500 (S130). The first controller 1480 may generate information about the driving of the first transfer robot 1400 based on information about the position of the second transfer robot 1500 received from the first camera 1460. In addition, the first controller 1480 may transmit information about the driving of the first transfer robot 1400 to the first driving unit 1470, and the first transfer robot 1400 may be docked to the second transfer robot 1500 through the first driving unit 1470.

Thereafter, the control method of the transfer unit may include transferring the carrier C loaded on the second upper stage 1530 of the second transfer robot 1500 to the first lower stage 1420 of the first transfer robot 1400 by the first robot arm 1440 (S140). After completing the transfer of the carrier C, the control method of the transfer unit may include undocking the first transfer robot 1400 from the second transfer robot 1500 (S150).

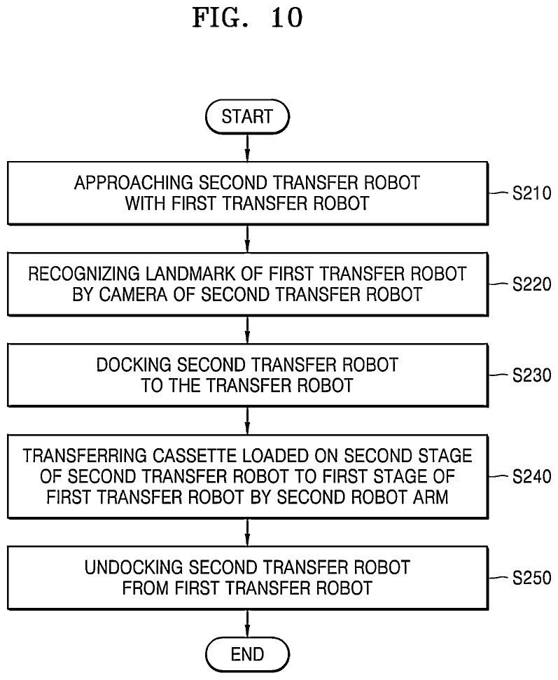

FIG. 10 is a flowchart sequentially showing a control method of a transfer unit according to an embodiment.

Referring to FIG. 10 together with FIGS. 4, 7, and 8 for convenience of explanation, the control method of the transfer unit according to an embodiment first may include an operation in which the second transfer robot 1500 approaches the first transfer robot 1400 (S210). Thereafter, the control method of the transfer unit may include recognizing the first landmark 1450a disposed on the first surface 1410a of the first transfer robot 1400 by the fourth camera 1560b disposed on the fourth surface 1510b of the second transfer robot 1500 (S220). At this time, the first landmark 1450 may include information that the surface to which the first landmark 1450a is attached is the first surface 1410a of the first transfer robot 1400. The fourth camera 1560b may transmit information about the position of the first transfer robot 1400 to the second controller 1580. Thereafter, the control method of the transfer unit may include docking the second transfer robot 1500 to the first transfer robot 1400 (S230). The second controller 1580 may generate information about the driving of the second transfer robot 1500 based on information about the position of the first transfer robot 1400 received from the fourth camera 1560b. The second controller 1580 may transmit information about the driving of the second transfer robot 1500 to the second driving unit 1570, and the second transfer robot 1500 may be docked to the transfer robot 1400 through the second driving unit 1570.

Thereafter, the control method of the transfer unit may include transferring the carrier C loaded on the second upper stage 1530 of the second transfer robot 1500 to the first lower stage 1420 of the first transfer robot 1400 by the second robot arm 1540 (S240). After completing the transfer of the carrier C, the control method of the transfer unit may include undocking the second transfer robot 1500 from the first transfer robot 1400 (S250).

As described above, example embodiments of the disclosure have been disclosed in the drawings and specification. In the present specification, the example embodiments are described by using some specific terms, but the terms used are for the purpose of describing the technical scope of the inventive concept only and are not intended to be limiting of meanings or the technical scope described in the claims. Therefore, it will be understood by those skilled in the art that various changes in form and details may be made therein without departing from the spirit and scope of the disclosure. Accordingly, the scope of the invention is defined not by the detailed description of the invention but by the appended claims.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A transfer robot which is configured to recognize a position of another robot loaded with a carrier and dock with the other robot,
the transfer robot providing a first surface and a second surface opposite to the first surface, the transfer robot comprising:
a lower stage providing a first space for loading the carrier loaded on the other robot;
a first camera disposed on the first surface and configured to recognize the position of the other robot and generate position information of the other robot;
a robot arm configured to hold the carrier;
a driving unit capable of aligning the transfer robot with the other robot by moving the transfer robot; and
a controller electrically connected to the first camera, the robot arm, and the driving unit to receive the position information generated by the first camera,
wherein the control unit is
configured to send a driving signal to the driving unit so that the transfer robot docks with the other robot based on the position information.

2. The transfer robot of claim 1, further comprising:
a first landmark attached to the first surface; and
a second landmark attached to the second surface,
wherein the first landmark includes position information that the surface to which the first landmark is attached is the first surface, and
the second landmark includes position information that the surface to which the second landmark is attached is the second surface.

3. The transfer robot of claim 2, wherein the first landmark and the second landmark are quick response (QR) code images.

4. The transfer robot of claim 1, wherein
the control unit sends an electrical signal to the robot arm to pick the carrier loaded on the other robot when the transfer robot docks with the other robot.

5. The transfer robot of claim 1, further comprising:
an upper stage providing a second space for loading the carrier,
wherein a vertical level from the lowest surface of the transfer robot of the upper stage is higher than a vertical level from the lowest surface of the transfer robot of the lower stage.

6. A transfer unit comprising:
a first transfer robot providing a space for transferring and loading a carrier including an object on shelves arranged in left-right and up-down directions, a first surface, and a second surface opposite to the first surface;
a second transfer robot providing a space for transferring and loading the carrier, a third surface, and a fourth surface opposite to the third surface; and
a crane provided in the left and right directions and a lifting belt provided along the crane and coupled to the first transfer robot and the second transfer robot,
wherein the first transfer robot includes:
a first landmark attached to the first surface;
a second landmark attached to the second surface; and
a first driving unit that moves the first transfer robot in the left and right direction or up and down directions,
wherein the second transfer robot includes:
a third landmark disposed on the third surface;
a fourth landmark disposed on the fourth surface; and
a second driving unit that moves the second transfer robot in the left and right direction or up and down direction.

7. The transfer unit of claim 6, wherein
the first landmark includes information that the surface to which the first landmark is attached is the first surface of the first transfer robot,
the second landmark includes information that the surface to which the second landmark is attached is the second surface of the first transfer robot,
the third landmark includes information that the surface to which the third landmark is attached is the third surface of the second transfer robot, and
the fourth landmark includes information that the surface to which the fourth landmark is attached is the fourth surface of the second transfer robot.

8. The transfer unit of claim 6, wherein
the first transfer robot includes:
a first lower stage providing a first space for loading the carrier; and
a first upper stage providing a second space for loading the carrier,
wherein a vertical level from the lowest surface of the first transfer robot of the first upper stage is higher than a vertical level from the lowest surface of the first transfer robot of the first lower stage.

9. The transfer unit of claim 8, wherein,
in the left and right direction, the first lower stage is positioned closer to the first landmark than the first upper stage.

10. The transfer unit of claim 6, wherein
the second transfer robot includes:
a second lower stage providing a third space for loading the carrier; and
a second upper stage providing a fourth space for loading the carrier,
wherein the vertical level from the lowest surface of the second transfer robot of the second upper stage is higher than the vertical level from the lowest surface of the second transfer robot of the second lower stage.

11. The transfer unit of claim 10, wherein,
in the left and right direction, the second upper stage is positioned closer to the fourth landmark than the second lower stage.

12. The transfer unit of claim 6, wherein
the first transfer robot includes:
a first camera disposed on the first surface;
a second camera disposed on the second surface; and
a first controller electrically connected to the first driving unit, the first camera, and the second camera.

13. The transfer unit of claim 12, wherein
the first camera is configured to receive position information about the second transfer robot by photographing the fourth landmark of the second transfer robot and transmit a driving signal of the first transfer robot to the first controller based on the position information.

14. The transfer unit of claim 6, wherein
the second transfer robot includes:
a third camera disposed on the third surface;
a fourth camera disposed on the fourth surface; and
a second controller electrically connected to the second driving unit, the third camera, and the fourth camera.

15. The transfer unit of claim 14, wherein
the third camera is configured to receive position information about the first transfer robot by photographing the third landmark of the first transfer robot and transmit a driving signal of the second transfer robot to the second controller based on the position information.

16. The transfer unit of claim 6, wherein
the first landmark, the second landmark, the third landmark, and the fourth landmark are quick response (QR) code images.

17. In a transfer robot system comprising a first transfer robot, a second transfer robot for loading carriers including semiconductor wafers on shelves arranged in a left-right direction and up-down direction, a crane provided in the left-right direction, and a lifting belt provided along the crane and coupled to the first transfer robot and the second transfer robot,
the first transfer robot providing a first surface comprises:
a first lower stage providing a first space for loading the carrier;
a first upper stage positioned at a higher vertical level than the first lower stage and providing a second space for loading the carrier;
a first landmark attached to the first surface, the first landmark including position information that the surface to which the first landmark is attached is the first surface;
a first camera disposed on the first surface; and
a first robot arm configured to hold the carrier, and
the second transfer robot providing a second surface comprises:
a second lower stage providing a second space for loading the carrier;
a second upper stage positioned at a higher vertical level than the second lower stage and providing a second space for loading the carrier;
a second camera configured to recognize the first landmark of the first transfer robot and generate position information of the first landmark;
a second robot arm configured to hold the carrier; and
a driving unit capable of moving the second transfer robot in one direction using the lifting belt,
wherein the second transfer robot drives the second robot arm to transfer the carrier loaded on the first upper stage when the first surface of the first transfer robot and the second surface of the second transfer robot face each other.

18. The transfer robot system of claim 17, wherein,
in left and right direction, the first lower stage is positioned closer to the first landmark than the first upper stage.

19. The transfer robot system of claim 17, wherein
the second transfer robot includes:
a second landmark attached to the second surface, the second landmark including position information that the surface to which the second landmark is attached is the second surface,
wherein the first transfer robot drives the first robot arm to transfer the carrier loaded on the second upper stage when the first surface of the first transfer robot and the second surface of the second transfer robot face each other.

20. The transfer robot system of claim 17, wherein the first landmark and the second landmark are quick response (QR) code images.
